(19) United States
(12) Patent Application Publication
(10) Pub. No.: US 2025/0241007 A1
(43) Pub. Date: Jul. 24, 2025

(54) PEDMOS Transistor Devices

(71) Applicant: pSemi Corporation, San Diego, CA (US)

(72) Inventors: Jagar Singh, Clifton Park, NY (US); Mari Saji, San Diego, CA (US); Akira Fujihara, San Diego, CA (US)

(21) Appl. No.: 18/420,465

(22) Filed: Jan. 23, 2024

(51) Int. Cl. H01L 29/78; H01L 21/265; H01L 21/285; H01L 29/04; H01L 29/08; H01L 29/10; H01L 29/165; H01L 29/40; H01L 29/66

(52) U.S. Cl. CPC H10D 30/657; H01L 21/26513; H01L 21/26586; H01L 21/28518; H10D 30/022; H10D 30/0281; H10D 30/603; H10D 30/797; H10D 62/155; H10D 62/371; H10D 62/405; H10D 62/822; H10D 64/111

(57) ABSTRACT

A P-type Extended Drain MOS (PEDMOS) FETs capable of high speed operation and the capability to withstand relatively high drain voltages. The PEDMOS device includes an active layer (preferably <110> orientated Si) having a P+ SiGe source region, a first P− Si drift region, a second P− SiGe drift region, and a P+ SiGe drain region. The SiGe regions exert compression on the N-type Si channel, improving hole mobility within the PEDMOS device and resulting in low leakage currents at active layer edges, low channel resistance, and good HCI and GIDL characteristics. Forming the SiGe regions may include etching voids in the Si active layer and depositing SiGe within the voids; implanting Ge into defined regions of the Si active layer; or etching partial voids in the Si active layer, depositing SiGe within the partial voids in contact with Si, and diffusing the Ge into the Si.

### BACKGROUND

### (1) Technical Field

This invention relates to electronic integrated circuits, and more particularly to electronic integrated circuits having metal-oxide-semiconductor field-effect transistors (MOSFETs).

### (2) Background

Virtually all modern electronic products-including laptop computers, mobile telephones, and electric cars—utilize MOSFET-based integrated circuits (ICs). A number of architectural variations exist for MOSFETs. The most common type of MOSFETs are N-type MOSFETs (NFETs), which have N+ doped source and drain regions abutting opposite sides of a channel region, which may be doped with P-type material or be intrinsic silicon for an enhancement-mode device. In contrast, P-type MOSFETs (PFETs) have P+ doped source and drain regions abutting opposite sides of a channel region, which may be doped with N-type material or be intrinsic silicon for an enhancement-mode device. Historically, NFETs have been preferred over PFETs for a number of applications that require high speed switching since the mobility of electrons, which are carriers in NFET devices, is greater than that of holes, which are the carriers in PFET devices.

NFETs have been adapted to withstand relatively high drain voltages. For example, N-type Extended Drain MOS (NEDMOS) FETs fabricated using SOI processes and Laterally-Diffused MOS (LDMOS) FETs fabricated using bulk silicon are common transistor devices capable of handling relatively high drain voltages. However, there appears to be little development of comparable high voltage PFET devices, owing largely to actual and perceived disadvantages of PFETs compared to NFETs.

The present invention is directed to novel P-type Extended Drain MOS (PEDMOS) FETs capable of high speed operation and the capability to withstand relatively high drain voltages.

### SUMMARY

The present invention encompasses novel P-type Extended Drain MOS (PEDMOS) FETs capable of high speed operation and the capability to withstand relatively high drain voltages as compared to a PMOS device without an extended drain or other features of the current invention. The novel PEDMOS device includes an active layer having a P+ SiGe source region, a first P− drain-side Si drift region, a second P− SiGe drain-side extended drift region, and a P+ SiGe drain region. The active layer preferably is Si having a <110>, <100>, or <111> orientation. The SiGe regions exert compression on the N-type Si channel within the active layer, thereby improving hole mobility within the PEDMOS device. Resulting PEDMOS devices exhibit improved hole mobility, low leakage currents at active layer edges, low channel resistance, good hot-carrier injection (HCI) characteristics, and gate-induced drain leakage (GIDL) characteristics.

Embodiments include a PEDMOS FET including a Si active layer that includes: an N-type Si channel region having a source-side edge and a drain-side edge, a P+ SiGe source region adjacent the source-side edge of the N-type channel region, a first P− Si drift region having a first side adjacent the drain-side edge of the N-type channel region, and having a second side, a second P− SiGe drift region having a first side adjacent the second side of the first P− Si drift region, and having a second side, and a P+ SiGe drain region adjacent the second side of the second P− SiGe drift region.

In some embodiments, forming the P+ SiGe source region, the second P− SiGe drift, and the P+ SiGe drain region includes etching voids in the Si active layer, and depositing SiGe within the voids.

In some embodiments, forming the P+ SiGe source region, the second P− SiGe drift, and the P+ SiGe drain region includes implanting Ge into defined regions of the Si active layer.

In some embodiments, forming the P+ SiGe source region, the second P− SiGe drift, and the P+ SiGe drain region includes etching partial voids in the Si active layer, depositing SiGe within the partial voids in contact with Si, and diffusing the Ge into the Si to form graded SiGe regions.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional view of an SOI IC structure for a first PEDMOS FET in accordance with the present invention.

FIG. 1B is a stylized cross-sectional view showing only the BOX layer and active layer of a variant of the PEDMOS FET of FIG. 1A.

FIG. 1C is a stylized cross-sectional view of an SOI IC structure for a second PEDMOS FET in accordance with the present invention.

FIG. 1D is a stylized cross-sectional view showing only the BOX layer and active layer of a variant of the PEDMOS FET of FIG. 1C.

FIG. 1E is a stylized cross-sectional view of an SOI IC structure for a third PEDMOS FET in accordance with the present invention.

FIG. 1F is a stylized cross-sectional view showing only the BOX layer and active layer of a variant of the PEDMOS FET of FIG. 1E.

FIGS. 2A-2H are cross-sectional stylized views of example fabrication stages for the novel PEDMOS FET of FIG. 1A.

FIGS. 3A-3B are cross-sectional stylized views of a first set of alternative fabrication stages for the novel PEDMOS FET.

FIGS. 4A-4B are cross-sectional stylized views of a second set of alternative fabrication stages for the novel PEDMOS FET.

FIGS. 5A-5C are cross-sectional stylized views of a third set of alternative fabrication stages for the novel PEDMOS FET.

FIG. 6 is cross-sectional stylized view of an alternative PEDMOS FET having a stepped insulating GOX layer.

FIG. 7A is a top plan view of a first configuration of a BTS structure for a PEDMOS device of the types described in this disclosure.

FIG. 7B is a top plan view of a second configuration of BTS structures for a PEDMOS device of the types described in this disclosure.

FIG. 7C is a top plan view of a third configuration of BTS structures for a PEDMOS device of the types described in this disclosure.

FIG. 8 is a process flowchart showing one process that is suitable for some contemporary IC front-end-of-line (FEOL) foundries.

FIG. 9 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses novel P-type Extended Drain MOS (PEDMOS) FETs capable of high speed operation and the capability to withstand relatively high drain voltages as compared to a PMOS device without an extended drain or other features of the current invention. The novel PEDMOS device includes an active layer having a P+ SiGe source region, a first P− drain-side Si drift region, a second P− SiGe drain-side extended drift region, and a P+ SiGe drain region. The active layer preferably is Si having a <110>, <100>, or <111> orientation. The SiGe regions exert compression on the N-type Si channel within the active layer, thereby improving hole mobility within the PEDMOS device. Resulting PEDMOS devices exhibit improved hole mobility, low leakage currents at active layer edges, low channel resistance, good hot-carrier injection (HCI) characteristics, and gate-induced drain leakage (GIDL) characteristics.

As FET device dimensions are scaled down (e.g., a 45 nm or smaller node fabrication node), the performance of PFETs comes closer to the performance of NFETs. For example, the gm (transconductance) and ft (unity current gain cut-off frequency) of a PFET with a gate length L_{G} of about 45 nm are about 90% of an NFET.

In addition, PFETs exhibit better hot-carrier injection characteristics compared to NFETs since holes have a significantly lower impact ionization rate; consequently, the rate of hole injection into the gate oxide will be significantly lower than with an NFET. A PFET also presents a lower gate-induced drain leakage (GIDL) channel.

Applicant has realized that a PEDMOS architecture having source and drain regions that include germanium (e.g., as a heterogeneous or homogenous SiGe alloy, including Ge-doped Si as well as graded Ge and Si mixtures), particularly PEDMOS architectures having a strained channel region with a gate length L_{G} of about 45 nm or less, can achieve a hole mobility that approximately equals—and in many embodiments exceeds—the electron mobility of NFET devices.

A further advantage of a PEDMOS architecture is that it uses an N-type channel, and thus results in low leakage current at active layer edges (no dopant segregation to cause leakage) and a low channel resistance, which increases the BV_{ON} of the device. Low bipolar action of a PFET at its source also improves the BV_{ON}. Due to the presence of an extended drift region, a PEDMOS architecture also has a high junction breakdown BV_{DSS} value.

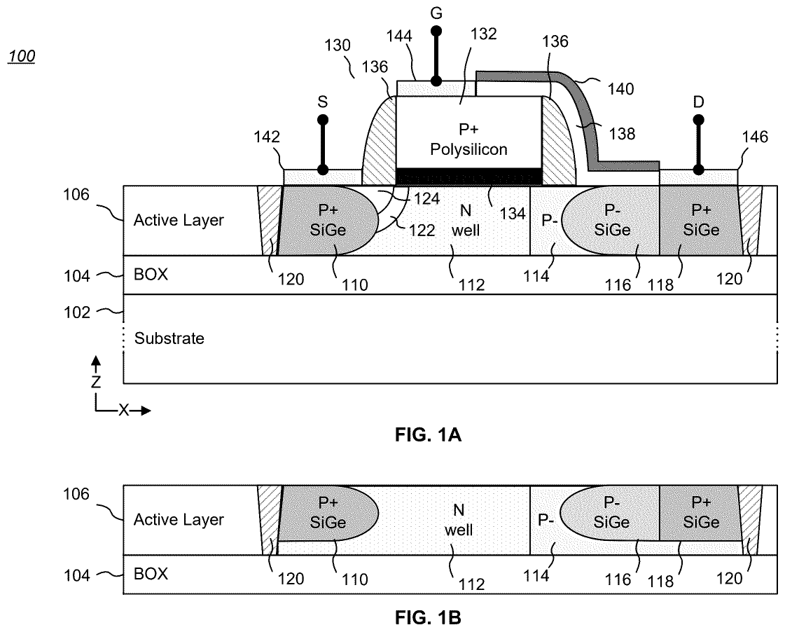

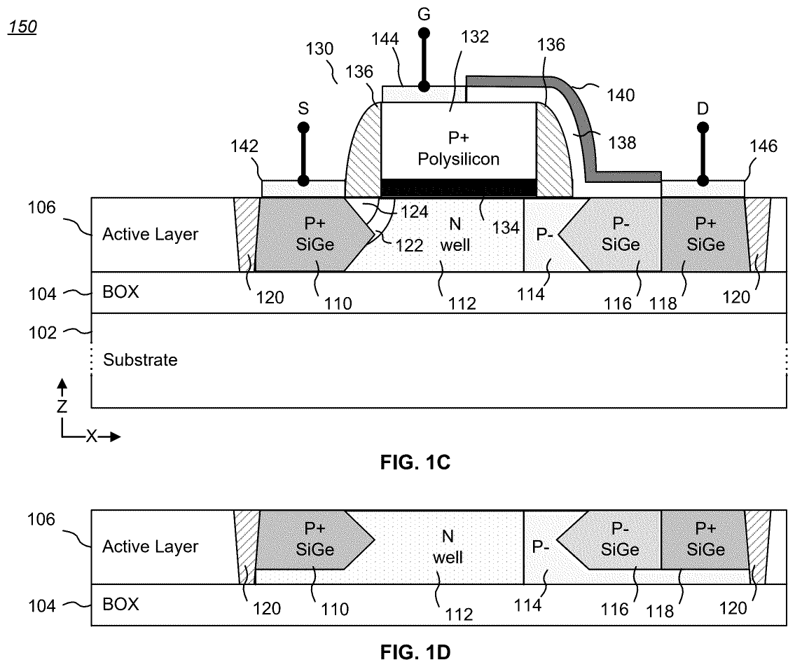

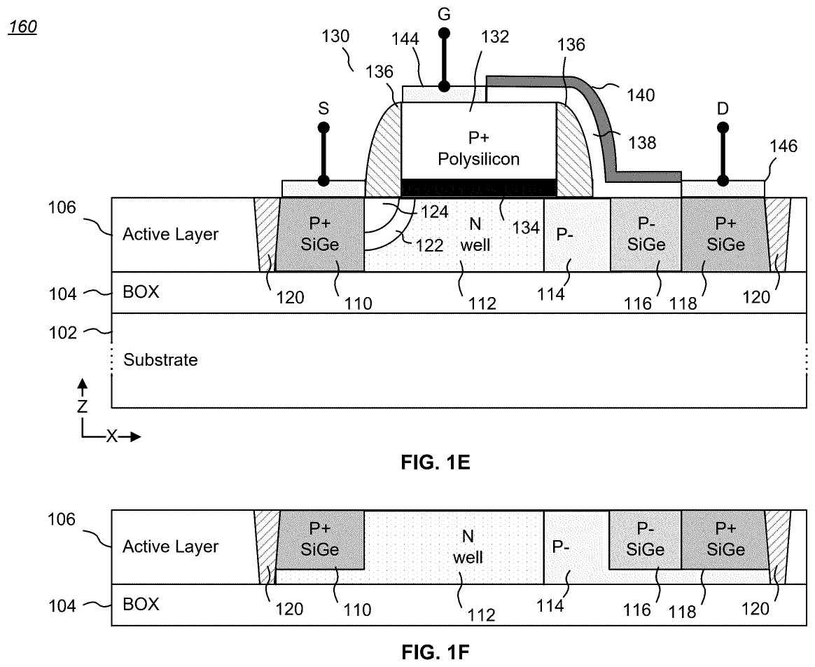

FIG. 1A is a stylized cross-sectional view of an SOI IC structure for a first PEDMOS FET 100 in accordance with the present invention. The SOI structure includes a substrate 102, a buried-oxide (BOX) insulator layer 104, and an active layer 106 (note that the dimensions for the elements of the SOI IC structure are not to scale; some dimensions have been exaggerated for clarity or emphasis). The substrate 102 is typically a semiconductor material such as silicon, but may be other materials such as glass or sapphire. The BOX layer 104 is a dielectric and is often SiO₂ formed as a “top” surface of the substrate 102; for some substrates (e.g., glass or sapphire, a BOX layer 104 optionally may be omitted. Some embodiments may include a trap-rich Si layer (not shown) between the BOX layer 104 substrate 102. A trap-rich Si layer mitigates parasitic surface conduction and improves device performance at high frequencies.

The active layer 106 may include some combination of implants and/or layers that include dopants, dielectrics, polysilicon, conductors, passivation, and other materials to form active and/or passive electronic components and/or mechanical structures. For example, FIG. 1A shows a PEDMOS FET 100 having an active layer 106 that includes a P+ source 110, an N-type body region or well 112 in which an electrically conductive channel can be formed, a first P− Si drift region 114, a second P− SiGe drift region 116, and a P+ drain 118, all bounded by an isolation structure 120, such as a shallow trench isolation (STI) structure. The designation “P− means a lesser concentration of P-type dopant (e.g., boron) than the designation “P+”.

Optional features within the active layer 106 include a halo region 122 and a lightly-doped drain (LDD) region 124 (“LDD” being somewhat of a misnomer, since the LDD region 124 is only on the source side for embodiments of the present invention). A halo implant mitigates punch-through while an LDD region mitigates avalanche breakdown. More specifically, the halo region 122 increases a sub-surface electric field to reduce so-called punch-through, or short channel, conduction between the source 110 and the drain 118, thus increasing the channel breakdown voltage. The LDD region 124 extends the source 110 underneath a gate structure 130 and modulates the threshold voltage V_{TH}, transconductance Gm, and leakage current of the device.

The gate structure 130 is formed in contact with a surface of the active layer 106, between the source 110 and the drain 118. The gate structure 130 includes a conductive layer 108, such as P+ doped polysilicon, in contact with an insulating gate oxide (GOX) layer 110, the thickness of which may be varied for different applications. In the illustrated example, the gate structure 130 is surrounded by insulating spacers 118. Part of the gate structure 130 and the P− drift regions 114, 116 are coated with a dielectric 138, such as SiO₂, Si₃N₄, etc., which in turn is overlaid with a salicide block (SAB) layer 140, such as silicon nitride (SiN), to prevent subsequent formation of silicide on those structures/regions.

A conductive source contact 142, a conductive gate contact 144, and a conductive drain contact 146, which may be self-aligned silicides (also known as “salicides”), are respectively formed in contact with the source 110, the gate structure 130, and the drain 118. Stylized electrical terminals S, G, and D are shown coupled to the corresponding source contact 142, gate contact 144, and drain contact 146.

The gate structure 130, the BOX layer 104 and the active layer 106 (which may include multiple FETs) may be collectively referred to as a “device region” or “substructure” for convenience (noting that other structures or regions may intrude into the substructure in particular IC designs). A superstructure (not shown) of various elements, regions, and structures may be fabricated on or above the substructure in order to implement particular functionality. The superstructure may include, for example, conductive interconnections from the illustrated FET 100 to other components (including other FETs on the same IC die) and/or external contacts, passivation layers, and protective coatings.

Importantly, the P+ source 110, the second P− drift region 116, and the P+ drain 118 all comprise Si and Ge in the form of a heterogeneous or homogenous SiGe alloy, including Ge-doped Si, graded Ge and Si mixtures, or the like. Hole mobility in Ge and SiGe generally is greater than hole mobility in Si alone, particularly when the active layer 106 has a <110> orientation. For example, in an active layer 106 of Si having a <110> orientation, Ge has about 4 to 5 times greater hole mobility than Si between 2 and 3 gigapascals (GPa), with various SiGe alloys having intermediate hole mobilities. However, increased hole mobility for Ge and SiGe also occurs in Si having a <100> or <111> orientation.

In FIG. 1A, the P+ source 110 and the P+ drain 118 are fabricated so that a portion of the SiGe extends into the source-side and drain-side edges of the channel region with a rounded shape resulting from use of a particular etchant (details below). The Si active layer 106 preferably has a <110> orientation, but may be Si having a <100> or <111> orientation. The introduction of Ge into Si increases the interatomic spacing within the crystal structure of the SiGe regions, thereby compressing the channel region of the device (within the N well 112). Such compression significantly improves hole mobility within the PEDMOS device.

FIG. 1B is a stylized cross-sectional view showing only the BOX layer 104 and active layer 106 of a variant of the PEDMOS FET 100 of FIG. 1A. In FIG. 1B, the P+ SiGe source 110, the second P− SiGe drift region 116, and the P+ SiGe drain 118 do not extend all the way down to the BOX layer 104 (the substrate 102, gate structure 130, halo region 122, and LDD region 124 are omitted to reduce clutter).

FIG. 1C is a stylized cross-sectional view of an SOI IC structure for a second PEDMOS FET 150 in accordance with the present invention. Similar in most aspects to the first PEDMOS FET 100 of FIG. 1A, the P+ source 110, the second P− drift region 116, and the P+ drain 118 are fabricated so that a portion of the SiGe extends into the source-side and drain-side edges of the channel region with an angled or pointed shape resulting from use of a particular etchant (details below). The Si active layer 106 preferably has a <110> orientation, but may be Si having a <100> or <111> orientation. Again, the introduction of Ge into Si increases the interatomic spacing withing the crystal structure of the SiGe regions, thereby compressing the channel region of the device to significantly improve hole mobility within the PEDMOS device.

FIG. 1D is a stylized cross-sectional view showing only the BOX layer 104 and active layer 106 of a variant of the PEDMOS FET 150 of FIG. 1C. In FIG. 1D, the P+ SiGe source 110, the second P− SiGe drift region 116, and the P+ SiGe drain 118 do not extend all the way down to the BOX layer 104.

FIG. 1E is a stylized cross-sectional view of an SOI IC structure for a third PEDMOS FET 160 in accordance with the present invention. Similar in most aspects to the first PEDMOS FET 100 of FIG. 1A, the P+ source 110 and the P+ drain 118 are fabricated so that the SiGe does not extend significantly into the channel region. Nevertheless, the introduction of Ge into Si increases the interatomic spacing withing the crystal structure of the SiGe regions, thereby compressing the channel region of the device to improve hole mobility within the PEDMOS device.

FIG. 1F is a stylized cross-sectional view showing only the BOX layer 104 and active layer 106 of a variant of the PEDMOS FET 160 of FIG. 1E. In FIG. 1F, the P+ SiGe source 110, the second P− SiGe drift region 116, and the P+ SiGe drain 118 do not extend all the way down to the BOX layer 104.

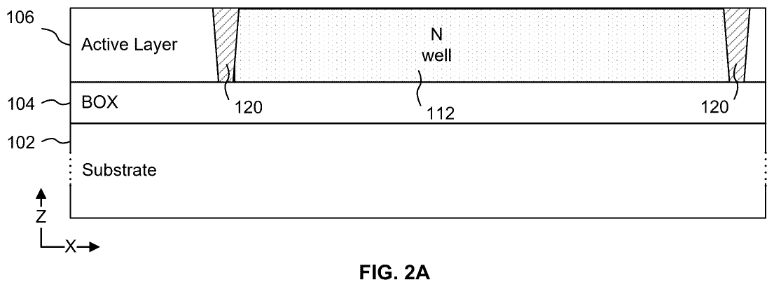

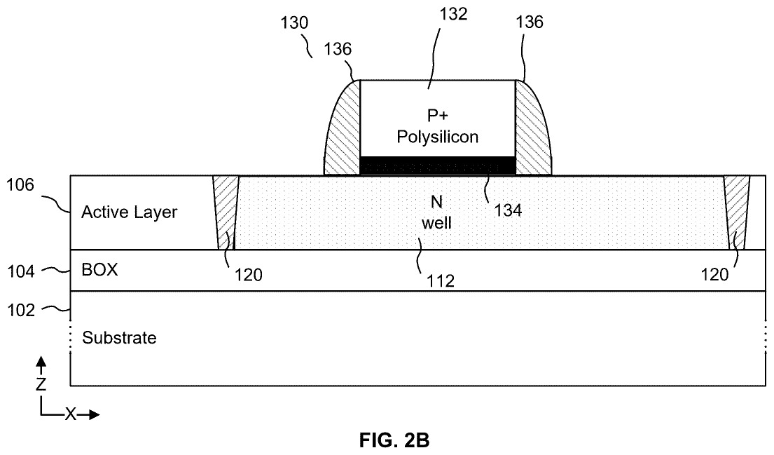

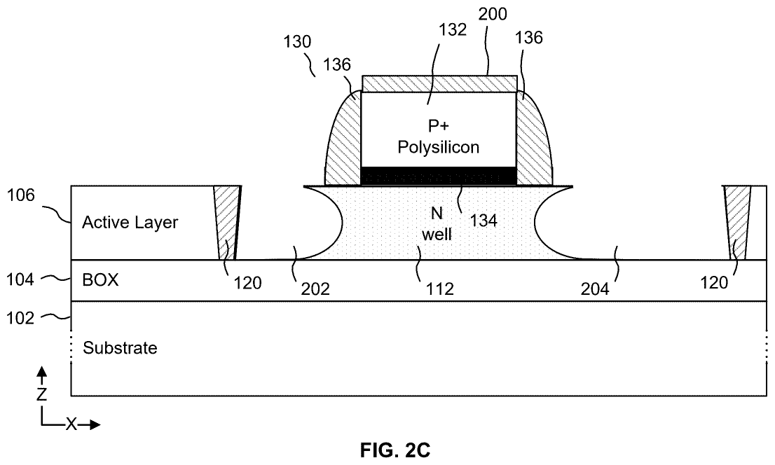

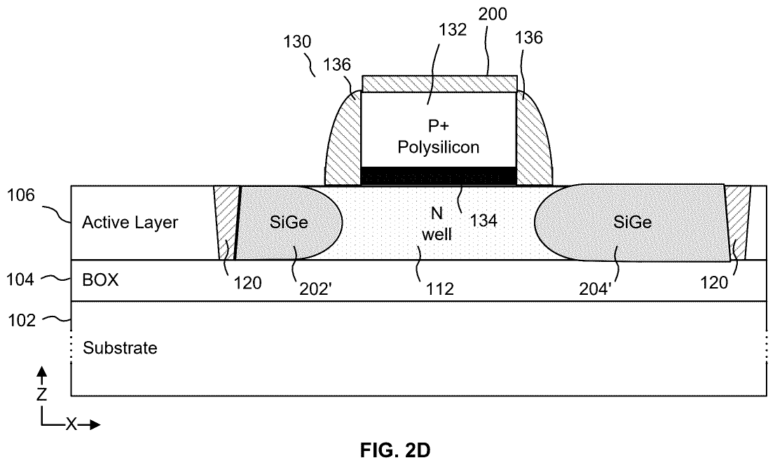

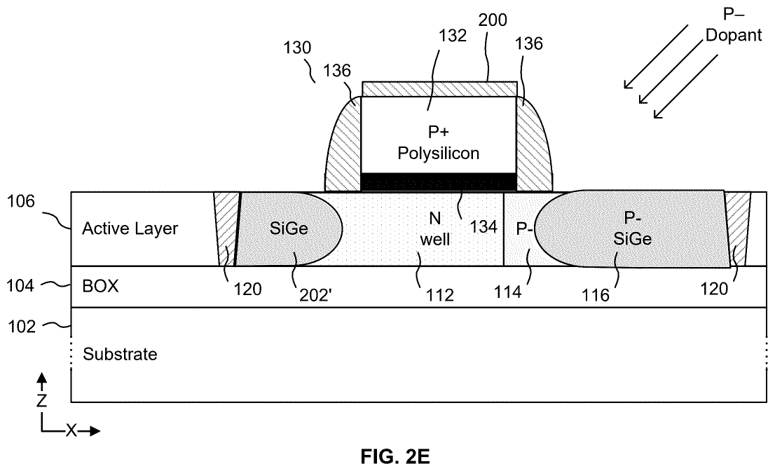

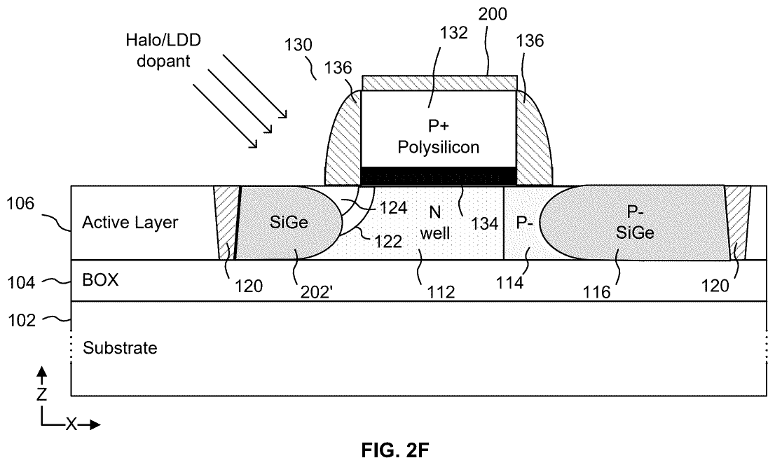

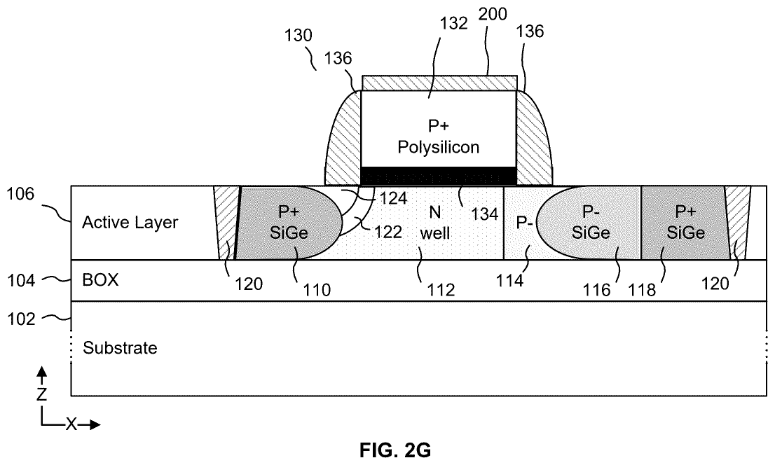

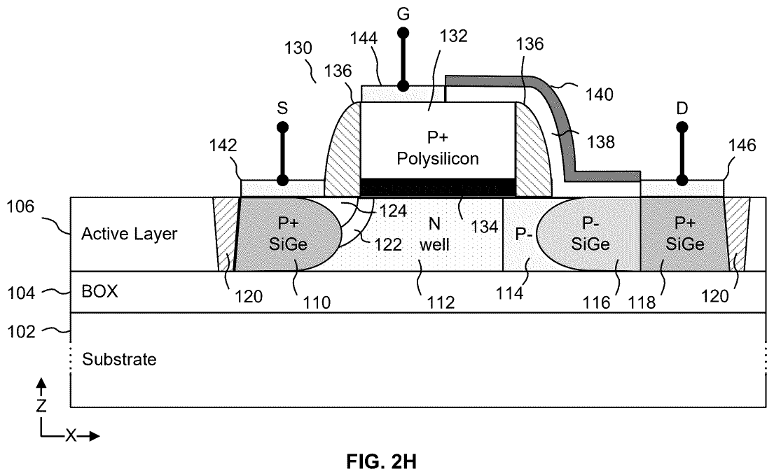

FIGS. 2A-2H are cross-sectional stylized views of example fabrication stages for the novel PEDMOS FET 100 of FIG. 1A, where the active layer 106 (by way of example only) is Si having a <110> orientation. The stages would be essentially the same for the PEDMOS FET 150 of FIG. 1C and the PEDMOS FET 160 of FIG. 1E with the exception of the selection of etchant for the regions in which the P+ SiGe source 110, the second P− SiGe drift region 116, and the P+ SiGe drain 118 are formed.

FIG. 2A shows a portion of an active layer 106 formed on a BOX layer 104, which is in turn formed on top of a substrate 102. Additionally, isolation structures 120 and a N-type body region or well 112 have been formed. In some embodiments, the active layer 106 may be formed directly on top of a bulk Si substrate 106, thus omitting the BOX layer 104, so long as some form of isolation is provided (and possibly a buried N+ layer). If needed, the semiconductor active layer 106 may be thinned to a suitable thickness, such as by chemical-mechanical polishing (CMP). For example, commercially available SOI wafers may have an active layer thickness of about 750 Å. It may be useful for some applications, particularly for RF ICs, to thin the active layer 106, for example, to about 500 Å.

FIG. 2B shows a gate structure 130 formed in contact with a surface of the active layer 106, between the source 110 and the drain 118. The gate structure 130 includes a conductive layer 132 (e.g., P+ doped polysilicon) in contact with an insulating gate oxide (GOX) layer 134, and surrounding insulating spacers 136. The gate structure 130 may be formed by conventional MOSFET fabrication processes such as thermal oxidation, epitaxial deposition, photolithographic masking and etching, etc.

FIG. 2C shows that an etchant block 200 of SiO₂ has been formed over the conductive layer 132 of the gate structure 130 and that the active layer 106 has been masked and etched to form voids 202, 204 within the active layer 106. Void 202 is the location where the P+ SiGe source 110 is to be formed and void 204 is the location there the second P− SiGe drift region 116 and P+ SiGe drain 118 are to be formed.

In FIG. 2C, the voids 202, 204 extend into the <110> channel material with a rounded shape resulting from use of an isotropic silicon etchant such as NH₄OH, KOH, or ethylenediamine pyrocatechol (EDP). A pointed shape for the voids matching the SiGe regions shown in FIG. 1C may be formed by using an anisotropic silicon etchant such as tetra methyl ammonium hydroxide (TMAH) or potassium hydroxide (KOH). Straight-walled voids matching the SiGe regions shown in FIG. 1E may be formed by using, for example, dry plasma etching. As shown in FIGS. 1B, 1D, and IF, the Z-dimension of the voids 202, 204 need not extend all the way down to the BOX layer 104, which may be controlled, for example, by the duration of etching. Indeed, it may be useful to leave a thin layer of Si within the voids 202, 204 to serve as a seed layer for subsequent epitaxial growth of a SiGe alloy.

FIG. 2D shows that the voids 202, 204 of FIG. 2C have been filled with a SiGe alloy, such as by chemical vapor deposition (CVD), to become filled SiGe regions 202′, 204′.

FIG. 2E shows that the active layer 106 on the drain-side of the gate structure 130 is doped (e.g., by angled ion implantation after suitable masking) with a P− material (e.g., boron) to form a first P− Si drift region 114 and a second P− SiGe drift region 116. The implantation is performed at an angle so that a portion of the N well material (including a portion underneath the gate structure 130) is converted into the first P− Si drift region 114. The angled implantation also transforms the SiGe in the filled void 204′ (see FIG. 2D) into the second P− SiGe drift region 116.

FIG. 2F shows that the active layer 106 on the source-side of the gate structure 130 is doped (e.g., by angled ion implantation after suitable masking) with a suitable dopant to form a halo region 122 and an LDD region 124 within the N well material (including a portion underneath the gate structure 130).

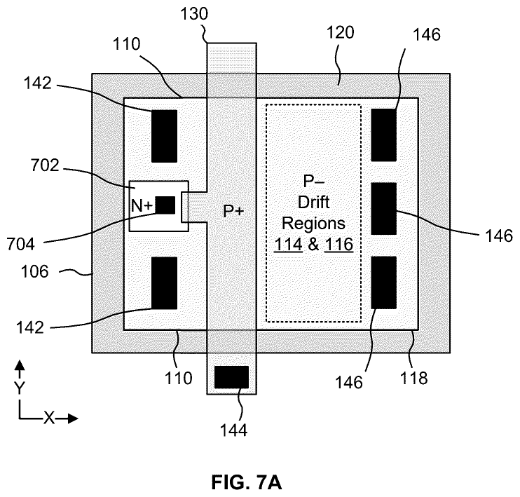

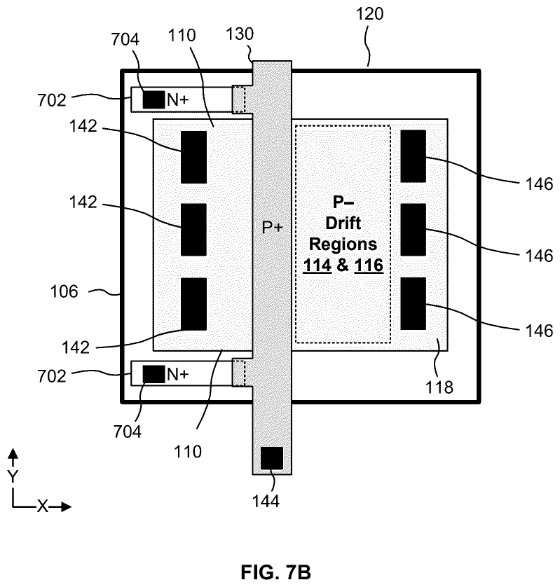

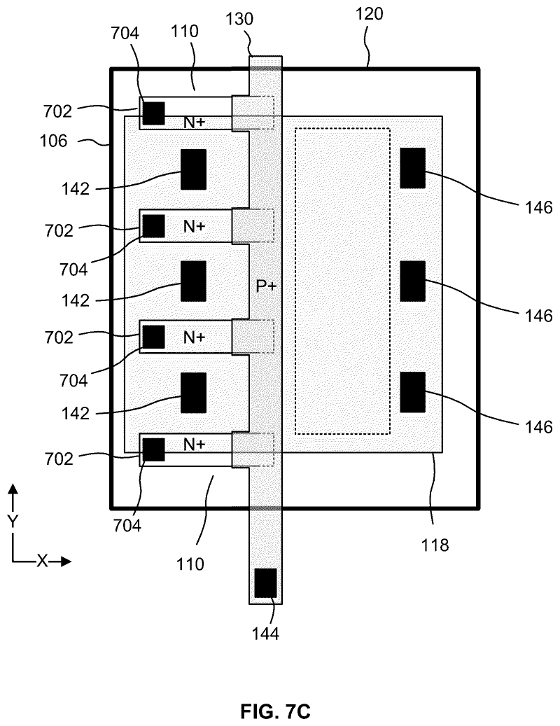

FIG. 2G shows that the SiGe filled void 202′ and a portion of the second P− SiGe drift region 116 of FIG. 2F have been defined by masking and then doped with a P+ dopant (e.g., boron) to transform those regions into the P+ SiGe source 110 and the P+ SiGe drain 118. Doping may be by ion implantation or diffusion. Subsequently, N+ material may be implanted in selective areas of the P+ SiGe source 110 and the P+ SiGe drain 118 to form body-tied-to-source connections (see FIGS. 7A-7C below for further details).

FIG. 2H shows that part of the etchant block 200 has been removed, part of the gate structure 130 and the exposed portions of the P− drift regions 116, 118 have been coated with a dielectric 138 (SiO₂, Si₃N₄, etc.), and a salicide block (SAB) layer 140 (e.g., SiN) has been formed over the dielectric 138. A conductive source contact 142, a conductive gate contact 144, and a conductive drain contact 146, which may be salicides, have been respectively formed in contact with the P+ SiGe source 110, the gate structure 130, and the P+ SiGe drain 118. Stylized electrical terminals S, G, and D are shown coupled to the corresponding source contact 142, gate contact 144, and drain contact 146.

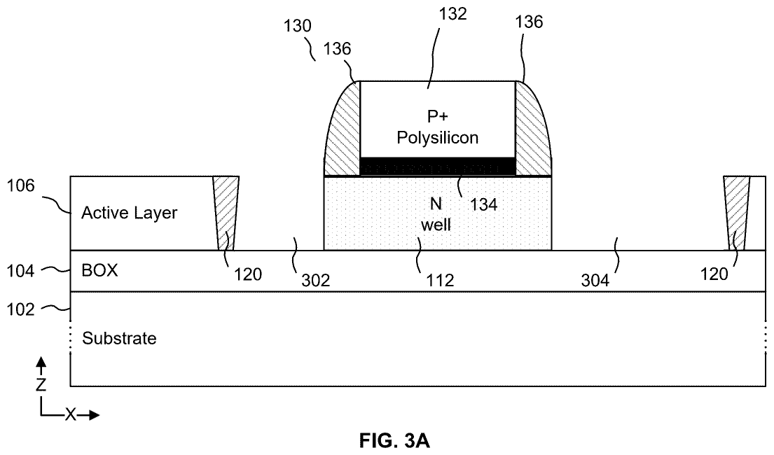

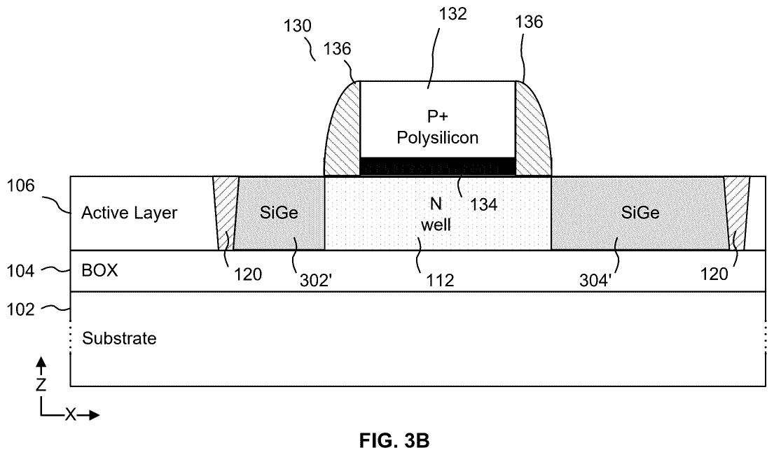

FIGS. 3A-3B are cross-sectional stylized views of a first set of alternative fabrication stages for the novel PEDMOS FET. The fabrication stages shown in FIGS. 2A-2B would be followed by the fabrication stage shown in FIG. 3A.

FIG. 3A shows that the active layer 106 has been masked and etched (e.g., by dry plasma etching) down to the BOX layer 104 to form vertical-sidewall voids 302, 304 within the active layer 106. Void 302 is the location where the P+ SiGe source 110 is to be formed and void 304 is the location there the second P− SiGe drift region 116 and P+ SiGe drain 118 are to be formed. In some embodiments, etching is stopped before reaching the BOX layer 104, as in the example shone in FIG. 1F.

FIG. 3B shows that the voids 302, 304 of FIG. 3A have been filled with a SiGe alloy (such as by CVD, LPCVD, or an epitaxial deposition like process), to become filled SiGe regions 302′, 304′. Fabrication may then continue as shown in FIGS. 2E-2H.

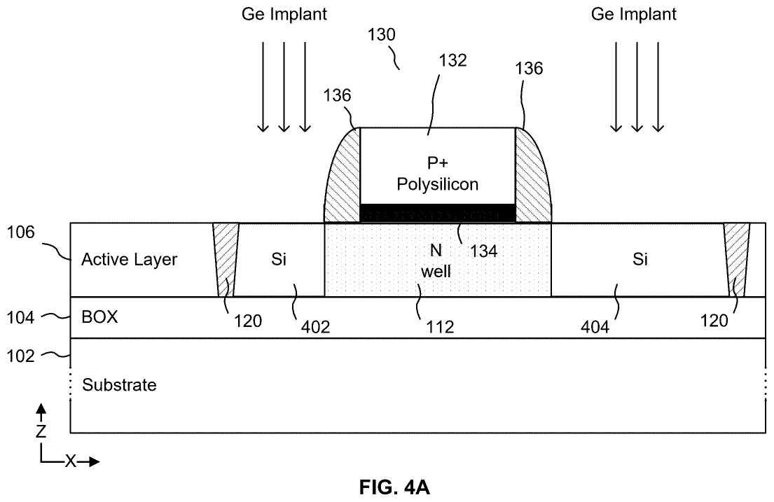

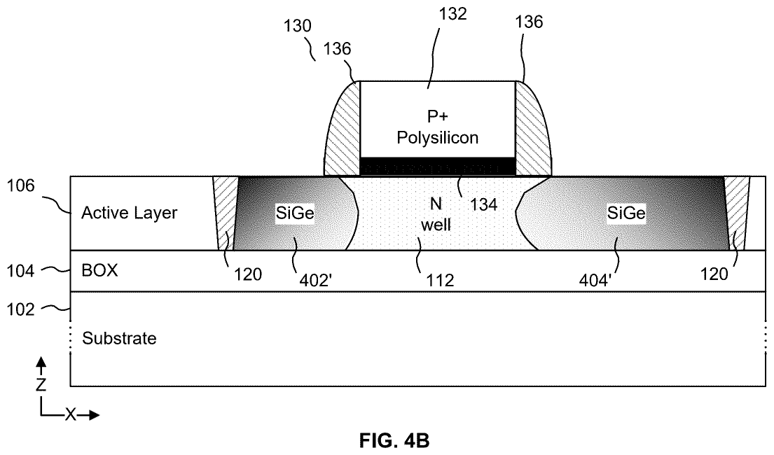

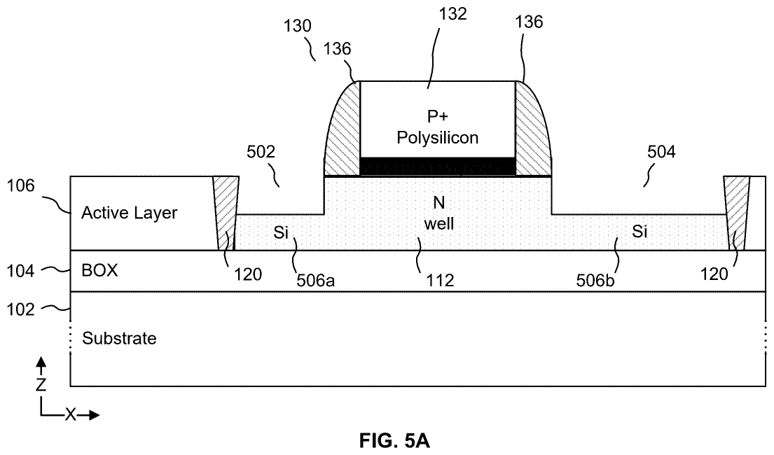

FIGS. 4A-4B are cross-sectional stylized views of a second set of alternative fabrication stages for the novel PEDMOS FET. The fabrication stages shown in FIGS. 2A-2B would be followed by the fabrication stage shown in FIG. 4A. FIG. 4A shows that the active layer 106 has been masked to define Si regions 402, 404 within the active layer 106 and that the defined regions 402, 404 are implanted (e.g., by ion implantation) with Ge. Region 402 is the location where the P+ SiGe source 110 is to be formed and region 404 is the location there the second P− SiGe drift region 116 and P+ SiGe drain 118 are to be formed.

FIG. 4B shows the device structure of FIG. 4A after implantation of Ge into the defined regions 402, 404 and annealing of the structure sufficiently to diffuse the Ge so as to create respective graded SiGe regions 402′, 404′. As illustrated, some of the diffused Ge may intrude into the channel region underneath the gate structure 130. The graded SiGe regions 402′, 404′ impose compression across the channel region, thus improving hole mobility. Fabrication may then continue as shown in FIGS. 2E-2H.

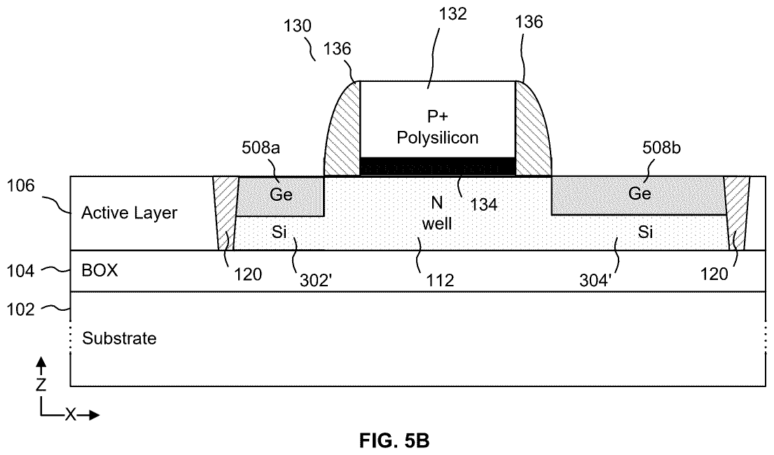

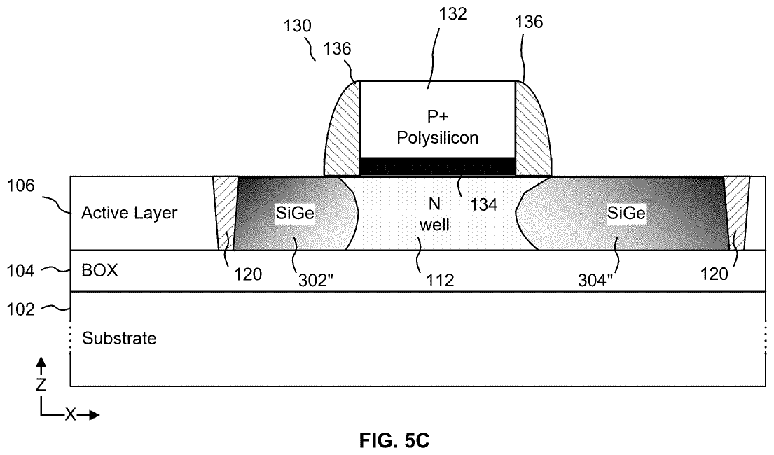

FIGS. 5A-5C are cross-sectional stylized views of a third set of alternative fabrication stages for the novel PEDMOS FET. The fabrication stages shown in FIGS. 2A-2B would be followed by the fabrication stage shown in FIG. 5A.

FIG. 5A shows that the active layer 106 has been masked and partially etched (e.g., by dry plasma etching) to form vertical-sidewall voids 502, 504 within the active layer 106, each with a Si base 506a, 506b (i.e., an unetched remainder of the silicon active layer 106). Void 502 and its underlying Si base 506a is the location where the P+ SiGe source 110 is to be formed and void 304 and its underlying Si base 506b is the location there the second P− SiGe drift region 116 and P+ SiGe drain 118 are to be formed.

FIG. 5B shows the device structure of FIG. 5A after deposition of Ge into regions 508a, 508b (e.g., by CVD) occupying the respective voids 502, 504 of FIG. 5A.

FIG. 5C shows the device structure of FIG. 5B after being subjected to heat treatment sufficient to diffuse the Ge regions 508a, 508b into the Si bases 506a, 506b to create respective graded SiGe regions 302″, 304″. As illustrated, some of the diffused Ge may intrude into the channel region underneath the gate structure 130. The graded SiGe regions 402′, 404′ impose compression across the channel region, thus improving hole mobility. In some embodiments, diffusion of Ge is controlled so as to not reach all of way to the BOX layer 104. Fabrication may then continue as shown in FIGS. 2E-2H.

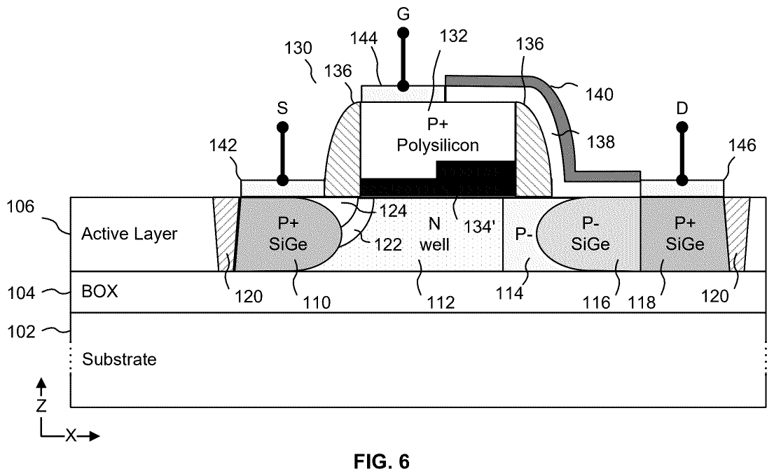

FIG. 6 is cross-sectional stylized view of an alternative PEDMOS FET having a stepped insulating GOX layer 134′. The stepped GOX layer 134′ includes a thin (in the Z dimension) subregion adjacent the source-side of the gate structure 130 and a thick subregion adjacent the drain-side of the gate structure 130. The thin and thick subregions of the stepped GOX layer 134′ will exhibit different V_{TH} characteristics. The thin GOX subregion creates a higher potential barrier when negative gate voltages are applied compared to a PEDMOS having only a thick GOX, resulting in a substantial improvement (˜25% in some embodiments) in the drain-to-source breakdown voltage V_{BD} of the device. The thicker GOX subregion at the drain-side of the gate structure 130 reduces the electric-field at the interface of the gate and the drain region and improves both GIDL and TDDB (Time-Dependent Dielectric Breakdown) for the device compared to a PEDMOS having only a thin GOX.

The stepped insulating GOX layer 134′ may be fabricated using additive or subtractive process steps. For example, an additive process may include forming a thin layer of GOX over the active layer 106, then masking the GOX to expose stripes over which additional oxide may be grown to form the thick regions, then removing the masking material (e.g., a photolithographic polymer). As another example, a subtractive process may include forming a thick layer of GOX over the active layer 106, then masking the GOX to protect stripes of thick GOX material, then etching the unprotected GOX to a desired thinness, then removing the masking material.

In the examples above, it may be useful to fabricate the spacers 136 to be asymmetric. For example, the thickness (in the X dimension) of the drain-side spacer 136 may be greater than the thickness of the source-side spacer 136. Asymmetric spacers may provide a higher device transconductance (Gm) and breakdown voltage due to being thin on the source-side of the gate structure 130 and thick on the drain-side of the gate structure 130 compared to symmetric spacers.

It is common to include a Body-Tied-to-Source (BTS) structure for MOSFETs, and a BTS configuration may be used with the inventive PEDMOS devices. A BTS structure in a PEDMOS device fabricated on an SOI substrate is of a special importance—the BTS structure eliminates or substantially mitigates the floating body current effect; mitigates turn-on of the parasitic bipolar devices inherent in the device; improves the breakdown voltage of the device; improves electro-static discharge (ESD) protection for the device; improves the output impedance of the device (very important for analog circuits); and improves device and circuitry performance and capability, and in particular improves circuit linearity, reliability, and power consumption in analog and digital circuitry, especially for such devices as RF and mmWave switches, low-noise amplifiers (LNAs), and power amplifiers (PAS).

FIG. 7A is a top plan view of a first configuration of a BTS structure for a PEDMOS device of the types described in this disclosure. Most of the component elements in the illustrated example have the same reference numbers as shown in FIG. 1A. One added element includes a centrally-located N+ body contact region 702 fabricated in a conventional manner to electrically connect to the body (i.e., the N well 112 in FIG. 1A) of the device to provide a fourth terminal to for the PEDMOS device. Also added is a contact 704 to the N+ region 702 that may be coupled to the source 110 through a device superstructure (not shown).

FIG. 7B is a top plan view of a second configuration of BTS structures for a PEDMOS device of the types described in this disclosure. Similar in many aspects to the device structure shown in FIG. 7A, the configuration shown in FIG. 7B includes two end-positioned BTS structures comprising N+ body contact regions 702 and associated contacts 704. Again, the associated contacts 704 may be coupled to the source 110 through a device superstructure (not shown). Placing the BTS structures along the X-dimension edges of the PEDMOS device reduces current leakage by increasing the V_{TH} at those edges. Having more than one BTS structure provides more efficient electron (e−) collection compared to the single central BTS structure shown in FIG. 7A.

The number of BTS structures may be increased in some embodiments. For example, FIG. 7C is a top plan view of a third configuration of BTS structures for a PEDMOS device of the types described in this disclosure. Similar in many aspects to the device structure shown in FIG. 7B, the configuration shown in FIG. 7C includes four BTS structures comprising N+ body contact regions 702 and associated contacts 704, with two of the BTS structures being end-positioned as in FIG. 7B. As should be clear, embodiments of the inventive PEDMOS device may have any desired number of BTS structures that fit within the confines of the PEDMOS device layout.

Note that not all steps that may be performed during the manufacture of PEDMOS devices as part of an IC are shown in aforementioned figures. Such steps may vary between IC foundries and may include (but are not limited to) substrate thinning, planarization, special implantations, annealing, formation of ohmic contacts, and formation of additional temporary or permanent structures (e.g., drift regions, substrate contacts, passivation layers, salicide blocks, replacement metal gate (RMG)), etc. After formation of a basic MOSFET structure, back-end-of-line (BEOL) processes may be applied, such as fabrication of electrical contacts (pads), vias, insulating layers (dielectrics), metallization layers, and bonding sites for die-to-package connections.

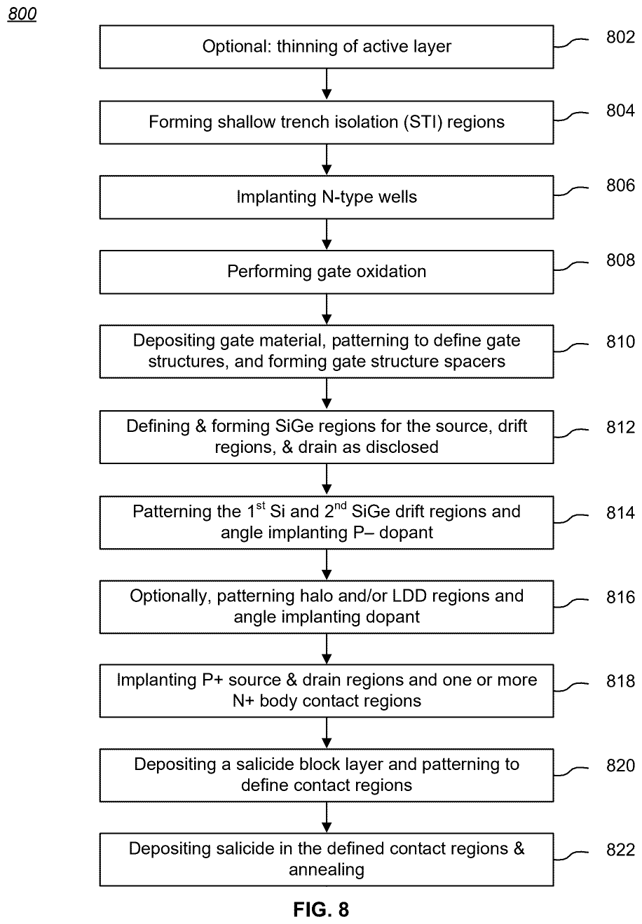

A number of different processes may be used to fabricate the IC architectures disclosed above. FIG. 8 is a process flowchart showing one process that is suitable for some contemporary IC front-end-of-line (FEOL) foundries. Note that some conventional steps, such as planarization, passivation, details of masking and etching, and superstructure formation have been omitted as known to those of ordinary skill in the art. The illustrated process includes:
(1) If needed, thinning the semiconductor active layer (e.g., Si, Ge, SiGe, SiC, or the like) formed on a substrate to a suitable thickness (Step 802).
(2) Forming shallow trench isolation (STI) regions (Step 804).
(3) Implanting N-type wells (Step 806).
(4) Performing gate oxidation (Step 808).
(5) Depositing gate material (e.g., P+ poly-Si), patterning (e.g., masking and etching) to define gate structures, and forming gate structure spacers (Step 810).
(6) Defining and forming SiGe regions for the source 110, second drift region 116, and drain 118 (Step 812). This may be done, for example, by etching voids in the active layer 106 and depositing SiGe within the voids (see, e.g., FIGS. 2C-2D and 3A-3B); implanting Ge into defined regions of the Si active layer 106 to form SiGe regions (see, e.g., FIGS. 4A-4B); or etching partial voids in the Si active layer 106, depositing Ge within the partial voids, and thermally diffusing the Ge into the Si to form graded SiGe regions (see, e.g., FIGS. 5A-5C).
(7) Patterning a first Si drift region 114 and the second SiGe drift region 116 and angle implanting P− dopant (Step 814)
(8) Optionally, patterning halo and/or LDD regions and angle implanting dopant (Step 816).
(9) Implanting P+ source S and drain D regions and one or more N+ body contact regions (Step 818).
(10) Depositing a salicide block layer and patterning to define contact regions (Step 820).
(11) Depositing salicide (e.g., NiSi) in the defined contact regions and annealing (Step 822).

As should be appreciated, other “recipes” that include additive and/or subtractive process steps may be used to fabricate essentially the same PEDMOS structures of the type described in this disclosure. Further, the fabrications steps may be performed in any feasible order.

While the examples of the invention disclosed above represent SOI IC PEDMOS structures, the invention may be used for a bulk semiconductor PEDMOS structure. It also should be appreciated that a number of features described above may be “mixed and matched” to create further variations without departing from the scope of the invention.

A PEDMOS device in accordance with the present invention may be combined with a NEDMOS device to provide a high-voltage complementary MOS (CMOS) device pair.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

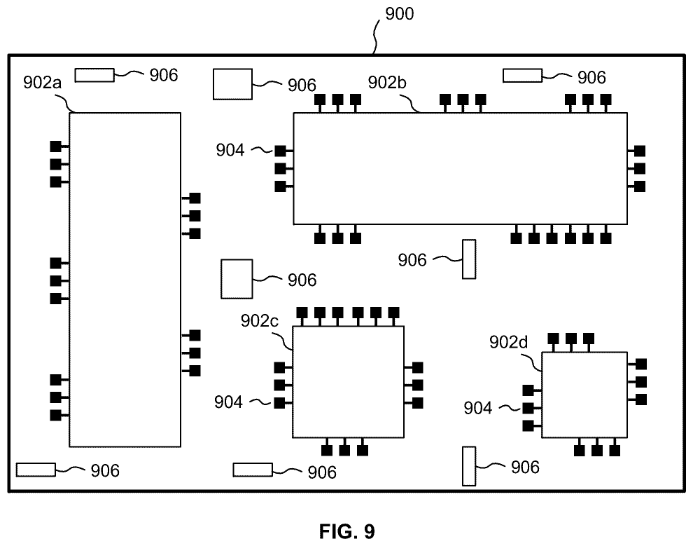

As one example of further integration of embodiments of the present invention with other components, FIG. 9 is a top plan view of a substrate 900 that may be, for example, a printed circuit board or chip module substrate (e.g., a thin-film tile). In the illustrated example, the substrate 900 includes multiple ICs 902a-902d having terminal pads 904 which would be interconnected by conductive vias and/or traces on and/or within the substrate 900 or on the opposite (back) surface of the substrate 900 (to avoid clutter, the surface conductive traces are not shown and not all terminal pads are labelled). The ICs 902a-902d may embody, for example, signal switches, active and/or passive filters, amplifiers (including one or more LNAs), and other circuitry. For example, IC 902b may incorporate one or more instances of a PEDMOS transistor fabricated in accordance with the teachings of this disclosure.

The substrate 900 may also include one or more passive devices 906 embedded in, formed on, and/or affixed to the substrate 900. While shown as generic rectangles, the passive devices 906 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 900 to other passive devices 906 and/or the individual ICs 902a-902d. The front or back surface of the substrate 900 may be used as a location for the formation of other structures.

Embodiments of the present invention are useful in a wide variety of larger radio frequency (RF) circuits and systems for performing a range of functions, including (but not limited to) RF power amplifiers, RF low-noise amplifiers (LNAs), antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, BCD, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A P-type extended drain metal-oxide-semiconductor (PEDMOS) field-effect transistor (FET) including a Si active layer that includes:
(a) an N-type Si channel region having a source-side edge and a drain-side edge;
(b) a P+ SiGe source region adjacent the source-side edge of the N-type channel region;
(c) a first P− Si drift region having a first side adjacent the drain-side edge of the N-type channel region, and having a second side;
(d) a second P− SiGe drift region having a first side adjacent the second side of the first P− Si drift region, and having a second side; and
(e) a P+ SiGe drain region adjacent the second side of the second P− SiGe drift region.

2. The PEDMOS FET of claim 1, wherein the active layer is formed on a buried-oxide insulator layer.

3. The PEDMOS FET of claim 1, wherein the buried-oxide insulator layer is formed on a substrate.

4. The PEDMOS FET of claim 1, wherein the P+ SiGe source region and the second P− SiGe drift region are shaped to compress the N-type Si channel region.

5. The PEDMOS FET of claim 4, wherein the P+ SiGe source region has a rounded shape adjacent the source-side edge of the N-type channel region and the second P− SiGe drift region has a rounded shape adjacent the drain-side edge of the N-type channel region.

6. The PEDMOS FET of claim 4, wherein the P+ SiGe source region has an angled shape adjacent the source-side edge of the N-type channel region and the second P− SiGe drift region has an angled shape adjacent the drain-side edge of the N-type channel region.

7. The integrated circuit of claim 1, wherein the Si active layer further includes a doped halo region between the P+ SiGe source region and the N-type Si channel region.

8. The integrated circuit of claim 1, wherein the Si active layer further includes a lightly-doped drain region between the P+ SiGe source region and the N-type Si channel region.

9. The PEDMOS FET of claim 1, wherein the active layer comprises Si having a <110> orientation.

10. An integrated circuit fabricated on a substrate and including:
(a) a Si active layer having a <110> orientation and which includes:
(1) an N-type Si channel region having a source-side edge and a drain-side edge;
(2) a P+ SiGe source region adjacent the source-side edge of the N-type channel region;
(3) a first P− Si drift region having a first side adjacent the drain-side edge of the N-type channel region, and having a second side;
(4) a second P− SiGe drift region having a first side adjacent the second side of the first P− Si drift region, and having a second side;
(5) a P+ SiGe drain region adjacent the second side of the second P− SiGe drift region; and
(b) a gate structure overlying the N-type Si channel region.

11. The integrated circuit of claim 10, wherein the Si active layer is formed on a buried-oxide insulator layer.

12. The integrated circuit of claim 11, wherein the buried-oxide insulator layer is formed on a substrate.

13. The integrated circuit of claim 10, wherein the P+ SiGe source region and the second P− SiGe drift region are shaped to compress the N-type Si channel region.

14. The integrated circuit of claim 13, wherein the P+ SiGe source region has a rounded shape adjacent the source-side edge of the N-type channel region and the second P− SiGe drift region has a rounded shape adjacent the drain-side edge of the N-type channel region.

15. The integrated circuit of claim 13, wherein the P+ SiGe source region has an angled shape adjacent the source-side edge of the N-type channel region and the second P− SiGe drift region has an angled shape adjacent the drain-side edge of the N-type channel region.

16. The integrated circuit of claim 10, wherein the Si active layer further includes a doped halo region between the P+ SiGe source region and the N-type Si channel region.

17. The integrated circuit of claim 10, wherein the Si active layer further includes a lightly-doped drain region between the P+ SiGe source region and the N-type Si channel region.

18. A method of fabricating a P-type extended drain metal-oxide-semiconductor (PEDMOS) field-effect transistor (FET), including:
(a) forming, within a Si active layer, an N-type Si channel region having a source-side edge and a drain-side edge;
(b) forming a P+ SiGe source region adjacent the source-side edge of the N-type channel region;
(c) forming a first P− Si drift region having a first side adjacent the drain-side edge of the N-type channel region, and having a second side;
(d) forming a second P− SiGe drift region having a first side adjacent the second side of the first P− Si drift region, and having a second side; and
(e) forming a P+ SiGe drain region adjacent the second side of the second P− SiGe drift region;
wherein the steps of forming may be performed in any feasible order.

19. The method of claim 18, further including forming a gate structure on the Si active layer and overlying the N-type Si channel region.

20. The method of claim 18, wherein forming the P+ SiGe source region, the second P− SiGe drift, and the P+ SiGe drain region includes:
(a) etching voids in the Si active layer; and
(b) depositing SiGe within the voids.

21. The method of claim 18, wherein forming the P+ SiGe source region, the second P− SiGe drift, and the P+ SiGe drain region includes implanting Ge into defined regions of the Si active layer.

22. The method of claim 18, wherein forming the P+ SiGe source region, the second P− SiGe drift, and the P+ SiGe drain region includes:
(a) etching partial voids in the Si active layer,
(b) depositing SiGe within the partial voids in contact with Si; and
(c) diffusing the Ge into the Si to form graded SiGe regions.
